(19) United States
(12) Patent Application Publication
(10) Pub. No.: US 2024/0213403 A1
(43) Pub. Date: Jun. 27, 2024

(54) SEMICONDUCTOR DEVICE AND METHOD FOR FORMING THE SAME

(71) Applicant: EPISTAR CORPORATION, Hsinchu (TW)

(72) Inventors: Tien-Yu WANG, Hsinchu (TW); Yung-Hsiang LIN, Hsinchu (TW)

(21) Appl. No.: 18/397,702

(22) Filed: Dec. 27, 2023

(30) Foreign Application Priority Data
Dec. 27, 2022 (TW) 111150222

(51) Int. Cl. H01L 33/12; H01L 33/00; H01L 33/20; H01L 33/48; H01L 33/60

(52) U.S. Cl. CPC H01L 33/12; H01L 33/007; H01L 33/20; H01L 33/486; H01L 33/60

(57) ABSTRACT

A semiconductor device includes a substrate having an upper surface, a buffer layer formed on the upper surface, and an element structure formed on the buffer layer. The substrate includes a plurality of holes extending from the upper surface of the substrate to an inside of the substrate and forming a plurality of openings at the upper surface of the substrate. In a cross-sectional view of the semiconductor device, at least two of the holes have different depths.

### CROSS-REFERENCE TO RELATED APPLICATIONS

This disclosure claims the right of priority of TW Application No. 111150222 filed on Dec. 27, 2022, and the content of which is hereby incorporated by reference in its entirety.

### BACKGROUND

### Technical Field

The present disclosure relates to a semiconductor device and method for forming the same, in particular, the semiconductor device includes a substrate and the substrate includes holes.

### Description of the Related Art

A semiconductor device includes compound semiconductors composed of group III-V elements, such as gallium phosphide (GaP), gallium arsenide (GaAs), gallium nitride (GaN), and aluminum nitride (AlN). The semiconductor device may be a semiconductor optoelectronic device, such as a light-emitting diode (LED), lasers, a light detector, a solar cell, power devices, or acoustic wave devices. With the rapid advancement of technology, the semiconductor device plays a very important role in some fields such as information transmission or energy conversion. Intended purposes of current semiconductor devices and forming method thereof have been achieved.

When the semiconductor device is a light-emitting diode, the device structure of the light-emitting diode includes a p-type semiconductor layer, an n-type semiconductor layer and an active region. The active region is located between the p-type semiconductor layer and the n-type semiconductor layer, so that under an external electric field, the electrons and electric holes respectively provided by the n-type semiconductor layer and the p-type semiconductor layer are recombined in the active region to convert electrical power into light power. The light-emitting efficiency of a light-emitting diode relate to internal quantum efficiency (IQE) and light extraction efficiency (LEE).

### SUMMARY

A semiconductor device of several embodiments of the present disclosure provide is provided. The semiconductor device includes a substrate having an upper surface, a buffer layer formed on the upper surface, and an element structure formed on the buffer layer. The substrate includes a plurality of holes extending from the upper surface of the substrate to an inside of the substrate and forming a plurality of openings at the upper surface of the substrate. In a cross-sectional view of the semiconductor device, at least two of the holes have different depths.

A method for forming a semiconductor device includes steps of: providing a substrate including an upper surface; epitaxially forming a buffer layer on the upper surface, and after forming the buffer layer, the substrate includes a plurality of holes, and a plurality of openings is formed by the plurality of holes at the upper surface of the substrate; and forming an element structure on the buffer layer.

### BRIEF DESCRIPTION OF THE DRAWINGS

FIGS. 1A and 1B are schematic cross-sectional views of multiple intermediate manufacturing stages of a semiconductor device in accordance with some embodiments of the present disclosure.

FIGS. 1C and 1D are schematic cross-sectional views of multiple intermediate manufacturing stages of a light-emitting device in accordance with some embodiments of the present disclosure.

FIG. 2 is a schematic top view of a substrate without the material layers above the substrate in accordance with some embodiments of the present disclosure.

FIGS. 3A, 3B, 3C, 3D, and 3E each are schematic top views of a substrate including holes in a semiconductor device in accordance with some embodiments of the present disclosure.

FIGS. 4A, 4B, 4C, 4D each are schematic cross-sectional views of a substrate including a plurality of holes in a semiconductor device in accordance with some embodiments of the present disclosure.

FIG. 5 illustrates a schematic cross-sectional view of growing a buffer layer on a substrate in accordance with some embodiments of the present disclosure.

FIGS. 6A, 6B, 6C, 6D and 6E each show schematic diagrams of various supply modes of different gas sources when depositing a buffer layer on a substrate in some embodiments of the present disclosure.

FIGS. 7A to 7E show schematic cross-sectional views of multiple intermediate stages of growing a buffer layer on a substrate in accordance with some embodiments of the present disclosure.

FIG. 8 is a schematic cross-sectional view of a light emitting package in accordance with some embodiments of the present disclosure.

FIG. 9 schematically shows a light emitting device in accordance with some embodiments of the present disclosure.

### DETAILED DESCRIPTION OF THE EMBODIMENTS

It is noted that each of the embodiments listed in the present application is merely used to describe the present application, not to limit the scope of the present application. It will be apparent to any one that obvious modifications or variations may be made to the devices in accordance with the present disclosure without departing from the spirit and scope of the present application. Identical or similar components in different embodiments or the components having identical reference numerals in different embodiments have identical physical properties or chemical properties. In addition, under suitable circumstances, the above-mentioned embodiments in the present application may be combined or replaced with each other, not limiting to the specific embodiments described above. In an embodiment, the connecting relationship of the specific component and other component described in detail may also be applied into other embodiments, falling within the scope of the following claims and their equivalents of the present application.

Furthermore, in some alternative embodiments, similar or identical components in the drawings of different embodiments are designated with similar/identical element symbols, so that detailed descriptions may be appropriately omitted. It is contemplated that elements and features of one embodiment may be advantageously incorporated into another embodiment without further elaboration. Furthermore, the drawings are drawn to facilitate understanding and clear explanation. The thickness, size, shape or positional relationship of each layer in the drawings does not exactly represent the actual size of the components or the actual proportions. It should be noted that components not shown in the drawings or described in the specification may be known to those skilled in the art.

In addition, spatially relative terms, such as “beneath,” “below,” “lower,” “above,” “upper”, “top”, “bottom” and the like, may be used herein for ease of description to describe one element or feature's relationship to another element(s) or feature(s) as illustrated in the drawings. The spatially relative terms are also used to describe the possible orientations of a semiconductor device in use or operation in addition to the orientation depicted in the drawings. The apparatus may be otherwise oriented (rotated 90 degrees or at other orientations) and the spatially relative descriptors used herein may likewise be interpreted accordingly.

A semiconductor device and method for forming the same is provided in some embodiments of the present disclosure. A substrate is formed with holes extended from an upper surface of the substrate to the inside of the substrate, wherein at least two of the holes have different depths. During the process of epitaxially growing the buffer layer on the substrate, the buffer layer is coalesced above the holes by a laterally epitaxial growth in regions devoid of the holes. Therefore, the extension directions of the defects may be changed, and the defects may be restrained in some regions, so the defect density of the following-grown epitaxial layer can be reduced, thereby improving the epitaxy qualities of the buffer layer and other semiconductor layers in the device structure above the buffer layer. In addition, when the semiconductor device is a light-emitting device, the substrate including the holes may be located on a light-emitting side of the light-emitting device. The holes may improve the light extraction efficiency of the light-emitting device, thereby increasing External Quantum Efficiency (EQE).

The semiconductor device in some embodiments may be semiconductor optoelectronic device, such as a light-emitting diode (LEDs), laser, light detector, solar cell, or power device. For example, the light-emitting device may include but not limited to an ultraviolet light-emitting diode (UV LED). The primary structure of a semiconductor device includes a buffer layer and a device structure formed on the buffer layer. Different device structures may be formed depending on the device functions. For example, the device structure of a light-emitting device may be a light-emitting stack including a p-type semiconductor layer, an n-type semiconductor layer and an active region. The active region may emit light in different wavelength bands in accordance with the material composition. A plurality of embodiments is provided below as relevant descriptions of the semiconductor device and the forming method thereof, and it is understood that each semiconductor device (including parts and layers) in these embodiments is for illustrative purposes only instead of intending to limit the present disclosure. Furthermore, other steps may be performed before, during or after each step described in the forming method proposed below, and some of the steps described above may be replaced or omitted in other embodiments of the method.

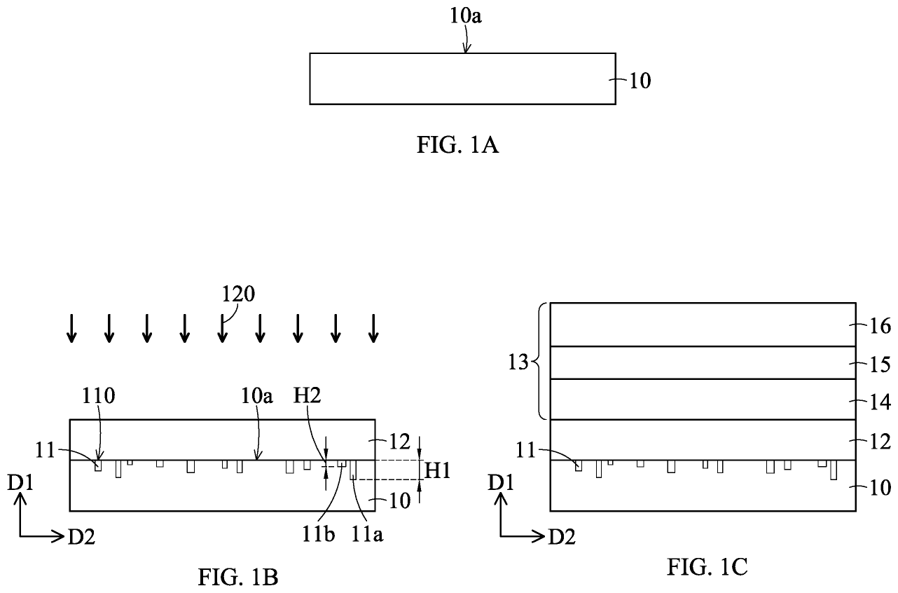

FIGS. 1A and 1B are schematic cross-sectional views of multiple intermediate manufacturing stages of a semiconductor device in accordance with some embodiments of the present disclosure. To be more specific, FIGS. 1A and 1B are schematic cross-sectional views of multiple intermediate manufacturing stages of a buffer layer of a semiconductor device in accordance with some embodiments of the present disclosure. FIGS. 1C and 1D are schematic cross-sectional views of multiple intermediate manufacturing stages of a light-emitting device 1 in accordance with some embodiments of the present disclosure. To be more specific, FIGS. 1C and 1D show an embodiment where the semiconductor device is the light-emitting device 1, which are cross-sectional views of multiple intermediate manufacturing stages where the device structure includes a semiconductor stack and electrodes.

Referring to FIG. 1A, a substrate 10 is provided in accordance with some embodiments, and the substrate 10 has an upper surface 10a. In some embodiments, the substrate 10 includes silicon, silicon carbide (SiC), sapphire (Al₂O₃), aluminum nitride (AlN), gallium nitride (GaN), gallium arsenide (GaAs), other proper materials for epitaxially growing compound semiconductor, or a combination of the foregoing. In an embodiment, the substrate 10 is a sapphire substrate.

Then, referring to FIG. 1B, according to some embodiments, a buffer layer 12 is formed on the substrate 10. As shown in FIG. 1B, the substrate includes a plurality of holes 11, and the plurality of holes 11 forms a plurality of openings 110 on the upper surface 10a of the substrate 10. Specifically, in some embodiments, the openings 110 of the holes are dispersed on the upper surface 10a of the substrate 10 and separated from each other. The openings 110 are randomly distributed on the upper surface 10a of the substrate 10, and the plurality of holes 11 extends downward from the upper surface 10a of the substrate 10 to the inside of the substrate 10. In accordance with some embodiments, the plurality of holes 11 extends downward to the inside of the substrate 10 along a single axial direction perpendicular to the upper surface 10a of the substrate 10. To be more specific, the extension directions of the holes 11 may not be changed, and the extension directions of the holes 11 may merely extend continuously downward to the inside of the substrate 10 along the single axial direction of the upper surface 10a perpendicular to substrate 10.

Because there is a lattice difference between the substrate 10 and the subsequent semiconductor material layer (or semiconductor stack) formed thereon, the buffer layer 12 can reduce the lattice mismatch between the substrate 10 and the semiconductor stack and may improve the epitaxy quality of the semiconductor stack. In some embodiments, the buffer layer 12 may include aluminum indium gallium nitride (AlInGaN) series materials, such as aluminum nitride (AlN), gallium nitride (GaN), aluminum gallium nitride (AlGaN), indium gallium nitride (InGaN), or other nitride-based semiconductor materials. In some embodiments, the buffer layer 12 may include a plurality of sublayers formed by alternating epitaxial growth or alternating deposition. The sublayers include the same or different materials, such as a combination of AlN, GaN and AlGaN. For example, the sublayers include at least two alternately-stacked AlGaN layers with different aluminum contents. In some embodiments, the buffer layer 12 may be further doped with carbon (C), hydrogen (H), and/or oxygen (O), and the doped concentration may be below 2E17 cm⁻³. In some embodiments, the percentage of aluminum (Al) content of the buffer layer 12 including aluminum nitride or aluminum gallium nitride is greater than that of the subsequently-formed semiconductor stack (e.g., the semiconductor light-emitting stack 13 including a first-type semiconductor layer 14 including aluminum gallium nitride).

In accordance with some embodiments, the buffer layer 12 may be formed on the upper surface 10a of the substrate 10 by metal organic chemical vapor deposition (MOCVD) process, molecular beam epitaxy (MBE) process, hydride vapor phase epitaxy (HVPE) process, ultrahigh vacuum chemical vapor deposition (UHV-CVD) process, physical vapor deposition (PVD) process or other proper processes.

In according to some embodiments of the disclosure, the plurality of holes 11 may be formed by removing a portion of the base material before, during, or after forming the buffer layer 12. The removing method include, for example, adjusting the parametric conditions for forming of buffer layer 12 to form the plurality of holes. For example, when the buffer layer 12 is epitaxially grown at an epitaxial growth temperature, a portion of the base material may be removed at the same time by a heat treatment, and the positions of the removed a portion of the base material are removed downward to a depth from the upper surface 10a where the buffer layer 12 is formed on, thereby the substrate 10 and the plurality of holes 11 may be formed. In another embodiment, the substrate 10 may be randomly etched irregularly by adjusting the parameter conditions in the duration of forming of the buffer layer 12, which includes supply modes of the reaction gas source, such as continuous supply, pulse supply, or a combination of two supply modes, or a combination of the supply mode of the reaction gas source and the epitaxial growth temperature, so that the substrate 10 may include the holes 11. These holes 11 extend from the upper surface 10a of the substrate 10 to the inside of the substrate 10, and form the openings 110 on the upper surface 10a of the substrate 10, and at least two holes 11 have different depths in the cross-sectional view of the semiconductor device. In accordance with another embodiment of the present disclosure, after forming the buffer layer 12 on the base material, the epitaxial growth may be stopped, and the base material may be heat-treated at a predetermined temperature, such as a high-temperature annealing in or after the epitaxial growth duration. In accordance with the embodiments of the present disclosure, during a process of epitaxially growing the buffer layer 12 on the substrate 10, the buffer layer 12 is coalesced above the holes by a laterally epitaxial growth in regions devoid of the holes. Therefore, the extension directions of the defects may be changed, and the defects may be restrained in some regions, so the defect density of the following-grown epitaxial layer can be reduced, thereby the epitaxy qualities of the buffer layer 12 and other semiconductor layers thereon in the device structure are improved. Embodiments of several formation methods for making the substrate 10 include the holes 11 will be described in detail below.

In a cross-sectional view, at least two holes 11 in the semiconductor device of an embodiment have different depths. As shown in FIG. 1B, the plurality of holes 11 has different depths along the first direction D1. For example, a hole 11a and a hole 11b are separated into two holes in the second direction D2, and an extended-downward depth H1 of hole 11a is different from a depth H2 of hole 11b. The depth H1 is greater than depth H2. The depth of each hole 11 described above refers to the distance measured from the upper surface 10a of the substrate 10 (i.e., the opening 110 of the hole 11) to the bottom surface of the hole 11. For example, the depths are perpendicular to the upper surface of the substrate 10.

Next, referring to FIGS. 1C and 1D, in accordance with some embodiments, an embodiment of taking the light-emitting device 1 as the semiconductor device is illustrated. A device structure, such as a semiconductor light-emitting stack 13, is formed on the buffer layer 12. The semiconductor light-emitting stack 13 includes sequentially formed layers: a first-type semiconductor layer 14, an active region 15, and a second-type semiconductor layer 16.

In some embodiments, the first-type semiconductor layer 14 and the second-type semiconductor layer 16 may serve as confinement layers, carrier supply layers, or contact layers. The active region 15 may serve as a light-emitting structure. The first-type semiconductor layer 14 and the second-type semiconductor layer 16 may include different dopant types of semiconductor materials for supplying carriers. For example, the first-type semiconductor layer 14 may include an n-type semiconductor layer, and the second-type semiconductor layer 16 may include a p-type semiconductor layer to respectively provide electrons and holes. Alternatively, the first-type semiconductor layer 14 may include a p-type semiconductor layer, and the second-type semiconductor layer 16 may include an n-type semiconductor layer to respectively provide holes and electrons. The first-type semiconductor layer 14, active region 15, and second-type semiconductor layer 16 may include the same series of III-V compound semiconductor materials, such as aluminum indium gallium arsenide (AlInGaAs) series, aluminum indium gallium phosphide (AlGaInP) series, arsenic indium gallium phosphide (InGaAsP) series, or aluminum indium gallium nitride (AlInGaN) series. Specifically, the AlInGaAs series may be represented as (Alₓ₁In(1-x1))₁₋ₓ₂Gaₓ₂As, AlInGaP series as (Alₓ₁In₍₁₋ₓ₁₎)₁₋ₓ₂Gaₓ₂P, AlInGaN series as (Alₓ₁In₍₁₋ₓ₁₎)₁₋ₓ₂Gaₓ₂N, and InGaAsP series as Inₓ₁Ga₁₋ₓ₁ Asₓ₂P₁₋ₓ₂, where 0≤x1≤1, and 0≤x2≤1. The wavelength of the light emitted by the light-emitting device 1 depends on the material composition of the active region 15. Specifically, the material of the active region 15 may include AlInGaAs, InGaAsP, AlGaInP, InGaN, or AlGaN. For example, when the material of the active region 15 is AlInGaP series, a red light with a wavelength between 610 nm and 650 nm or green light with a wavelength between 530 nm and 570 nm may be emitted. When the material of the active region 15 is InGaN series, a blue light with a wavelength between 400 nm and 490 nm, a cyan light with a wavelength between 490 nm and 530 nm, or a green light with a wavelength between 530 nm and 570 nm may be emitted. When the material of the active region 15 is AlGaN series or AlInGaN series, an ultraviolet light with a wavelength between 400 nm and 250 nm may be emitted. In some embodiments, the active region 15 may include a single heterostructure, double heterostructure, single quantum well, or multi-quantum wells (MQW). In some embodiments, the active region 15 includes one or more quantum well layers and one or more barrier layers alternately stacked in a Z direction, and a bandgap of each barrier layer is greater than that of each quantum well layer to limit carrier distribution. Additionally, without limitation in the present disclosure, the quantum well layers may have the same or different material compositions and bandgaps with each other. In some embodiments, the material of the active region 15 may be i-type, p-type, or n-type semiconductor.

In one embodiment, the light-emitting device 1 may be an ultraviolet light-emitting diode with a wavelength less than 320 nm, specifically, a UV-B light-emitting diode or UV-C light-emitting diode. In the present embodiment, the material of the semiconductor light-emitting stack 13 may be AlGaN series, or the average aluminum content of the semiconductor light-emitting stack 13 is between 0.1 and 1. In another embodiment, the light-emitting device 1 may be an ultraviolet light-emitting diode emitting a dominant wavelength less than 285 nm. Specifically, the light-emitting device 1 may be a deep ultraviolet (Deep UV) light-emitting diode or UV-C light-emitting diode. In the present embodiment, the material of the semiconductor light-emitting stack 13 may be AlGaN series, or the average aluminum content of the semiconductor light-emitting stack 13 is between 0.3 and 1. In the present embodiment, the first-type semiconductor layer 14, for example, is an n-type impurity-doped aluminum gallium nitride (n-AlGaN) layer having single composition. In some other embodiments, the first-type semiconductor layer 14, for example, is a multilayer structure including at least two n-AlGaN layers with different aluminum (Al) contents grown or deposited alternately, where the aluminum content can be between 0.1 and 1. In an embodiment of a UV-C light-emitting diode, the aluminum content of the first-type semiconductor layer 14 can be between 0.3 and 1.

In an embodiment, the active region 15, for example, is a single quantum well structure formed by stacking one quantum well layer and one or more barrier layers. In another embodiment, the active region 15, for example, is a multiple quantum well structure and formed by alternatingly stacking multiple quantum well layers and multiple barrier layers. In an embodiment, the active region 15 may include at least two quantum well structures, and each of them is formed by alternately stacking one or more quantum well layers and one or more barrier layers. In an embodiment, the aluminum (Al) contents of these two quantum-well structures may be the same or different. In one embodiment, the pair numbers that the quantum well layers alternate with the barrier layers of the two quantum-well structures may be the same or different. The well layers and barrier layers may include aluminum gallium nitride (AlGaN), where the aluminum content can be between 0.1 and 1. In an embodiment of a UV-C light-emitting diode, the aluminum content in the structure can be between 0.3 and 1. In an embodiment, the second-type semiconductor layer 16 can be aluminum gallium nitride (AlGaN) with an aluminum content, for example, between 0.1 and 1 and doped with p-type impurities. In an embodiment of a UV-C light-emitting diode, the aluminum content can be between 0.3 and 1.

The first-type semiconductor layer 14, the active region 15, and the second-type semiconductor layer 16 described above may be formed by, for example, metal-organic chemical vapor deposition (MOCVD) process, ultra-high vacuum chemical vapor deposition (UHV-CVD) process, molecular beam epitaxy (MBE) process, hydride vapor phase epitaxy (HVPE) process, or other proper processes.

Subsequently, the semiconductor light-emitting stack 13 may be etched by optical lithography and etching processes to remove a portion of the first-type semiconductor layer 14, a portion of the active region 15, and a portion of the second-type semiconductor layer 16, thereby forming a semiconductor mesa and a patterned first-type semiconductor layer 14′ having different thicknesses, as shown in FIG. 1D. In an embodiment, a mask (such as patterned photoresist, not shown) may be formed on the stack material of the semiconductor light-emitting stack 13 by processes like inductively coupled plasma (ICP) etching, reactive ion etching (RIE), or other proper processes, a portion of the second-type semiconductor layer 16 and a portion of the active region 15 outside the mask may be removed, and a portion of the first-type semiconductor layer 14 may be thinned. Subsequently, the mask is removed.

Referring to FIG. 1D, in accordance with some embodiments, after optical lithography and etching processes, a patterned semiconductor light-emitting stack 13′ is formed. The patterned semiconductor light-emitting stack 13′ includes a patterned first-type semiconductor layer 14′ and a semiconductor mesa thereon. The patterned first-type semiconductor layer 14′ includes a portion with a smaller thickness outside the semiconductor mesa and the other portion with a thicker thickness below the semiconductor mesa. The semiconductor mesa includes a patterned active region 15′ and a patterned second-type semiconductor layer 16′ on the patterned active region 15′. Subsequently, a first electrode 17 is formed on the patterned second-type semiconductor layer 16′, and a second electrode 18 is formed on the patterned first-type semiconductor layer 14′.

In some embodiments, the patterned second-type semiconductor layer 16′ of the light-emitting device 1 is a p-type semiconductor layer. Therefore, the first electrode 17 electrically connected to the p-type semiconductor layer may serve as a p-electrode as well, such as a p-metal electrode. In some embodiments, the patterned first-type semiconductor layer 14′ is an n-type semiconductor layer. Therefore, the second electrode 18 electrically connected to the n-type semiconductor layer may serve as an n-electrode as well, such as an n-metal electrode.

In some embodiments, the material of the first electrode 17 and/or the second electrode 18 includes a high work function metal material, such as nickel (Ni), gold (Au), silver (Ag), aluminum (Al), palladium (Pd), platinum (Pt), vanadium (V), zirconium (Zr), chromium (Cr), titanium (Ti), rhodium (Rh) or transparent conductive materials such as titanium nitride (TiN), indium tin oxide (ITO), indium zinc oxide (IZO), or a combination of the above-mentioned materials. Furthermore, the first electrode 17 and the second electrode 18 may be a single-layer structure or a multi-layer structure. To simplify the drawings, the first electrode 17 and the second electrode 18 in the embodiments are shown as a single-layer structure, but the present disclosure is not limited thereto.

As shown in FIG. 1D, a material for forming the p-electrode may be deposed on the second-type semiconductor layer 16 by e-beam evaporation, magnetron sputtering or other proper methods, and then the first electrode 17 may be formed by optical lithography and etching processes. Similarly, a material for forming the n-electrode may be deposed on the patterned first-type semiconductor layer 14′ by electron beam evaporation, magnetron sputtering or other proper methods, and the second electrode 18 may be formed by optical lithography and etching processes. Furthermore, in some embodiments, an annealing process may be further performed on the first and second electrodes 17 and 18 to eliminate internal defects of the electrode materials, such as eliminating residual stress between different metal materials.

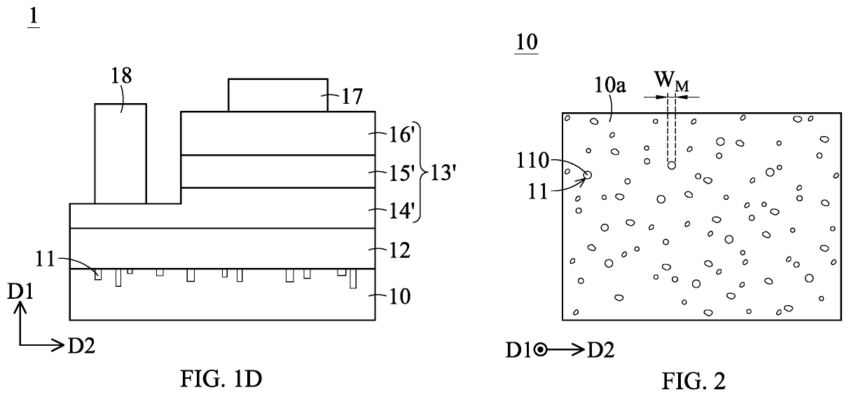

FIG. 2 is a schematic top view of a substrate without the material layers above the substrate in accordance with some embodiments of the present disclosure. In some embodiments, taking the light-emitting device 1 as an embodiment, after removing the buffer layer 12, the patterned semiconductor light-emitting stack 13′, and the first and second electrodes 17 and 18 by etching or grinding, a cross-sectional surface and a top surface (upper surface 10a) of the substrate 10 may be observed. Then at least two of the holes 11 are formed and have different depths toward the substrate 10 (for example, along the first direction D1), and the openings 110 are formed and are randomly distributed on the upper surface 10a of the substrate 10. That is, the holes 11 of the embodiment are irregularly distributed and formed in the substrate 10, whether on the upper surface 10a of the substrate 10 or extending into the inside of the substrate 10.

In some embodiments, the distribution density of the openings 110 on the upper surface 10a of the substrate 10 is between 1E7 cm⁻² and 1E10 cm⁻². In some embodiments, the distribution density of the openings 110 on the upper surface 10a of the substrate 10 is between 1E8 cm⁻² and 1E10 cm⁻².

Furthermore, in accordance with some embodiments, the holes 11 may have different sizes. As shown in FIG. 2, the sizes of the openings 110 of the holes 11, such as the maximum width W_{M} marked in the drawing (along the first direction D1) are different. In some embodiments, at least two openings 110 have different maximum widths W_{M} on the upper surface 10a of the substrate 10. In some embodiments, the differences and variations in size between the openings 110 of the holes 11 may be irregular.

In one embodiment, the maximum width W_{M} of each of the openings 110 on the upper surface 10a of the substrate 10 is not greater than 150 nm. In some embodiments, the maximum width W_{M} of each of the openings 110 on the upper surface 10a of the substrate 10 is between 1 nm and 100 nm. In some embodiments, the maximum width W_{M} of each of the openings 110 on the upper surface 10a of the substrate 10 is between 5 nm and 75 nm. Furthermore, in some embodiments, the maximum width difference of at least two openings 110 is between 5 nm and 100 nm.

In addition, the maximum width W_{M} of each of the openings 110 on the upper surface 10a of the substrate 10 is approximately close to or not greater than the maximum wavelength of the light emitted by the active region 15. In some embodiments, the maximum width W_{M} of each of the openings 110 is less than or equal to the maximum wavelength of the light emitted by the active region 15. In an embodiment that the active region 15 emits deep ultraviolet-C light (ultraviolet-C; UVC), the deep ultraviolet band has a dominant wavelength less than 285 nm, and the maximum width W_{M} of the opening 110 is no more than (i.e., less than or equal to) 285 nm.

Each of the holes 11 has an opening 110 extended from the upper surface 10a to the inside the substrate 10, and a refractive index of the plurality of holes 11 is different from that of the substrate 10, so that when the light is emitted into the substrate 10, it may be refracted due to the difference in refractive index between the holes and the substrate 10, thereby suppressing total internal reflection (TIR). In some embodiments, since the maximum width W_{M} of the opening 110 is closer to the deep ultraviolet light band than the visible light band, the light-extraction improvement for a deep ultraviolet light emitting diode applying the holes 11 may be more significant.

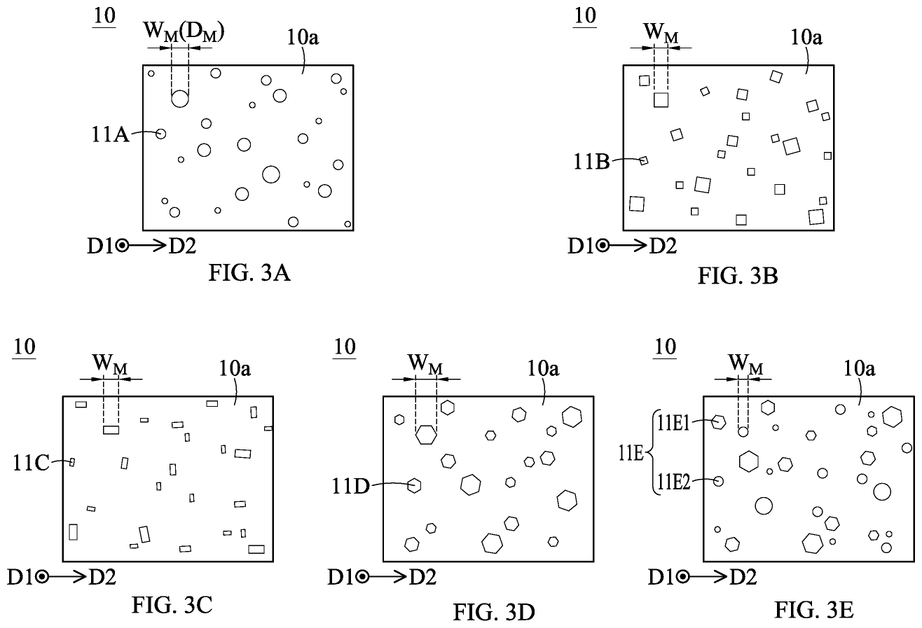

FIGS. 3A, 3B, 3C, 3D, and 3E are schematic top views of a substrate including holes in a semiconductor device in accordance with some embodiments of the present disclosure. In an actual process, if the holes 11 formed in the embodiment are observed with a scanning electron microscope (SEM), various shapes of openings 110 may be shown on the upper surface 10a of the substrate 10, such as circular, elliptical, quadrilateral (such as square, rectangular or rhombus), hexagonal, similar to the above-mentioned shapes.

Referring to FIG. 3A, in some embodiments, each hole 11A forms a circular opening on the upper surface 10a of the substrate 10. The circular openings are irregularly distributed on the upper surface 10a of the substrate 10, and the sizes (diameters) of the circular openings are not exactly the same. For example, at least two circular openings have different maximum widths W_{M} (i.e., diameters D_{M}) on the upper surface 10a of the substrate 10. In some embodiments, the diameter of each circular opening is less than or equal to the maximum wavelength of the light emitted by the active region 15. In some embodiments, the diameter of each circular openings is between 1 nm and 100 nm, or between 5 nm and 75 nm. In some embodiments, a diameter difference of the at least two circular openings is between 5 nm and 100 nm.

Referring to FIGS. 3B, 3C, and 3D, in some embodiments, the holes 11B, 11C, and 11D respectively form square, rectangular, and hexagonal openings on the upper surface 10a of the substrate 10. These polygonal openings also present an irregular distribution on the upper surface 10a of the substrate 10. For example, the distances between the polygonal openings of the holes 11B (or holes 11C or holes 11D) may be different. Furthermore, the opening sizes of these polygon openings are not exactly the same. For example, for the upper surface 10a of one substrate 10, at least two polygon openings have different maximum widths W_{M}. The maximum widths W_{M} may be the widest sides of the polygon openings, as shown in FIGS. 3B and 3D. Alternatively, the maximum widths W_{M} may be the diagonal lengths of the polygon openings, as shown in FIG. 3D. Similarly, in some embodiments, each maximum width W_{M} of these polygonal openings is less than or equal to the maximum wavelength of the light emitted by the active region 15. In some embodiments, the maximum width W_{M} of each polygonal opening is between 1 nm and 100 nm, or between of 5 nm and 75 nm. In some embodiments, the maximum width difference of at least two polygon openings is between 5 nanometers and 100 nanometers. Furthermore, as shown in FIGS. 3B, 3C and 3D, for the upper surface 10a of the substrate 10, the symmetry axes of these square, rectangular or hexagonal openings may be along approximately the same direction or along different directions.

Furthermore, for the substrate 10, the holes 11E may present at least two or more different shapes of openings on the upper surface 10a of the substrate 10. Referring to FIG. 3E, in some embodiments, each hole 11E1 forms a hexagonal opening on the upper surface 10a of the substrate 10, and each hole 11E2 forms a circular opening on the upper surface 10a of the substrate 10. The openings of the holes 11E are also irregularly distributed on the upper surface 10a of the substrate 10, and the sizes of the openings are not exactly the same. The exemplary relevant values of the maximum width W_{M} of these openings may be found in the above disclosure.

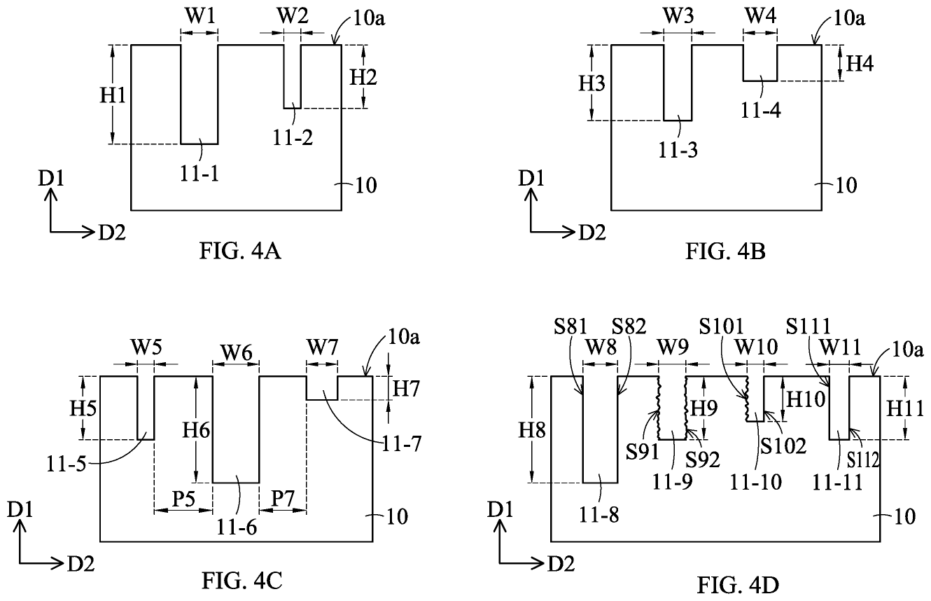

FIGS. 4A, 4B, 4C, 4D are schematic cross-sectional views of a substrate including a plurality of holes in a semiconductor device in accordance with some embodiments of the present disclosure. As mentioned above, in a cross-sectional view of the semiconductor device, at least two or more holes of the substrate 10 have different depths. In some embodiments, in addition to the openings of the holes being irregularly distributed on the upper surface 10a of the substrate 10, the depths of the respective holes (along the first direction D1) are also different.

Referring to FIG. 4A, in some embodiments, adjacent holes 11-1 and 11-2 have different depths H1 and H2, respectively, wherein the depth H1 is greater than the depth H2. The openings of adjacent holes 11-1 and 11-2 on the upper surface 10a of the substrate 10 respectively have different maximum widths W1 and W2. The maximum width W1 is greater than the maximum width W2. In the embodiment, the depth H1 is greater than the depth H2, and the maximum width W1 is greater than maximum width W2, but the present disclosure is not limited thereto.

Referring to FIG. 4B, in some embodiments, adjacent holes 11-3 and 11-4 have different depths H3 and H4 respectively, wherein the depth H3 is greater than the depth H4. The openings of adjacent holes 11-3 and 11-4 on the upper surface 10a of the substrate 10 respectively have different maximum widths W3 and W4, wherein the maximum width W4 is greater than the maximum width W3. In the embodiment, the depth H4 is less than the depth H3, and the maximum width W4 is greater than the maximum width W3, but the present disclosure is not limited thereto.

Referring to FIG. 4C, in some embodiments, adjacent holes 11-5, 11-6 and 11-7 have different depths H5, H6 and H7 respectively. The openings respectively have different maximum widths W5, W6 and W7 on the upper surface 10a of the substrate 10. The depth H6 is greater than the depth H5, and the depth H5 is greater than the depth H7 (i.e., H6>H5>H7). The maximum width W7 is greater than the maximum width W6, and the maximum width W6 is greater than the maximum width W5 (i.e., W7>W6>W5). Furthermore, for example, a spacing P5 may be between the adjacent holes 11-6 and the holes 11-5, and a spacing P7 may be between the adjacent holes 11-6 and the holes 11-7. The spacing P7 is different from the spacing P5. In the embodiment, the spacing P7 is greater than the spacing P5, and the holes 11-7 may have a greater maximum width W7, but the present disclosure is not limited thereto.

In the foregoing embodiments of FIGS. 4A to 4C, the holes have substantially smooth sidewalls, but the present disclosure is not limited thereto. Some of the holes 11 of the substrate 10 may have rough sidewalls.

Referring to FIG. 4D, in some embodiments, adjacent holes 11-8, 11-9, 11-10 and 11-11 have different depths H8, H9, H10 and H11 respectively. The openings on the upper surface 10a of the substrate 10 respectively have different maximum widths W8, W9, W10 and W11. In some embodiments, some of the holes, such as holes 11-9 and 11-10, respectively have rough sidewalls. In some embodiments, the surface roughness of the sidewalls of at least two holes 11 may be different. For example, among two adjacent holes 11, one hole has smooth sidewalls, while the sidewall surface of the other hole has irregular protrusions, in other words, the hole may have rough sidewalls. In some embodiments, in a cross-sectional view, two side walls of one hole may have different surface roughness.

In some embodiments, as shown in FIG. 4D, the hole 11-8 has smooth sidewalls S81 and S82, the hole 11-11 has smooth sidewalls S111 and S112; and the hole 11-9 has rough sidewalls S91 and S92 respectively opposite to the smooth sidewall S81 of the hole 11-8 and the rough sidewall S101 of the hole 11-10. The hole 11-10 has a rough side wall S101 and a relatively smooth side wall S102 respectively opposite to the hole 11-9 and the hole 11-11. In addition, the side wall S91, the side wall S92 and the side wall S101 may have different roughness or similar roughness. In accordance with some embodiments, the rough sidewalls of a hole may scatter light, thereby suppressing total internal reflection (TIR).

Referring to FIGS. 1B to 1D and 4A to 4D, in accordance with some embodiments, the depth of each hole 11 in a cross-sectional view (such as the depths H1 to H11 in FIGS. 1B and 4A to 4D) is respectively between 10 nm and 200 nm. In some embodiments, the depth of each of the holes 11 is between 20 nm and 200 nm. Furthermore, in some embodiments, the depth difference of at least two holes 11 is between 5 nm and 100 nm.

In addition, the depth of each hole 11 formed in a cross-sectional view (for example, the depths H1 to H11 in FIGS. 1B and 4A to 4D) is approximately close to or not greater than the maximum wavelength of the light emitted by the active region 15. In some embodiments, the depth of each hole 11 is less than the maximum wavelength of the light emitted by the active region 15. In some embodiments, the depth of each hole 11 is less than the maximum wavelength of the light emitted by the active region 15. In an embodiment where the active region 15 emits deep ultraviolet light (wavelength between 100 nm to 285 nm), the depth of each hole 11 can be less than 285 nm.

In some embodiments, the depth of each hole 11 is not greater than twice the minimum wavelength of light emitted by active region 15. In an embodiment where the active region 15 emits deep ultraviolet light (wavelength is 100 nm to 285 nm), the depth of each hole 11 can be not greater than 200 nm. In some embodiments, since the depth of the hole 11 is closer to the deep ultraviolet light band than the visible light band, the light-extraction improvement for a deep ultraviolet light emitting diode applying the holes 11 may be more significant.

In addition, in some embodiments, the holes 11 of the substrate 10 are extended vertically into the substrate 10, such as extended along the first direction D1. For example, when the substrate 10 is a sapphire substrate, since the sapphire crystal grows along the C-axis, when the buffer material is epitaxially grown on the substrate 10 and the upper surface 10a of the substrate 10 is etched at the same time, the etching direction with respect to the upper surface 10a is generally vertical instead of oblique. Therefore, the holes 11 extend perpendicularly into the substrate 10.

Based on the above, for the substrate 10 including the holes 11 of the foregoing embodiments, during the process of epitaxially growing the buffer layer 12 on the substrate 10, the buffer layer 12 may be coalesced above the holes by a laterally epitaxial growth in regions devoid of the holes. Therefore, the extension directions of the defects may be changed, and the defects may be restrained in some regions, so the defect density of the following-grown epitaxial layer can be reduced, thereby the epitaxy qualities of the buffer layer 12 and other semiconductor layers thereon in the semiconductor device are improved. In addition, the substrate 10 including the holes 11 may be located on the light-emitting side of the light-emitting device 1. Since the upper surface 10a of the substrate 10 is destructed, total internal reflection of light may be interrupted, thereby the light extraction efficiency of the light-emitting device 1 may be improved. Specifically, the holes 11 irregularly distributed and having different depths may further destruct total internal reflection of light. Furthermore, in accordance with some embodiments, the substrate 10 (such as a sapphire substrate), the holes 11 (which may contain air inside) and the buffer layer 12 (such as an aluminum nitride layer) respectively have three different refractive indexes, and the total internal reflection of light may be reduced according to the differences of refractive index, thereby improving the light extraction efficiency of the light-emitting device 1.

The following embodiments describe the forming method of the holes 11.

In accordance with some embodiments of the present disclosure, a variety of different forming methods are provided so that the substrate 10 may include the holes 11 described above. In an embodiment, a base material may be provided before forming the buffer layer 12, and a portion of the base material is removed downward to a depth by a photolithography etching process, thereby the substrate 10 and the holes 11 can be formed. In accordance with other embodiments of the present disclosure, a base material may be provided before forming the buffer layer, a heat treatment may be provided to the base material at a predetermined temperature, a portion of the base material may be removed by the heat treatment, and the substrate 10 and holes 11 are formed finally. The predetermined temperature may be equal to, lower than, or higher than a forming temperature of the buffer layer 12. In an embodiment, a base material may be provided, and then the buffer layer 12 is formed on the base material. During the formation of the buffer layer 12, a portion of the base material is removed. For example, when the buffer layer 12 is epitaxially grown at an epitaxial growth temperature, a portion of the base material may be removed downward to a depth from the upper surface 10a where the buffer layer 12 is formed on at the same time by a heat treatment, thereby the substrate 10 and the holes 11 may be formed. In an embodiment, in or after forming the buffer layer 12 on the base material, the epitaxial growth is stopped, and a heat treatment at a predetermined temperature is applied to the based material to remove a portion of the base material, so the substrate 10 and the holes 11 are formed finally. The predetermined temperature may be equal to, lower than, or higher than a forming temperature of the buffer layer 12. In an embodiment, a base material may be provided, and during the formation of the buffer layer 12, a portion of the base material is removed by adjusting the parameter conditions, thereby the substrate 10 and the holes 11 may be formed. The parameter conditions include supply modes of the reactive gas source such as continuous supply, pulse supply, or a combination of two supply modes or a combination of the supply modes and the heat treatment. In accordance with the holes 11 and the forming method thereof proposed in the embodiments, not only the epitaxy qualities of the buffer layer 12 and other semiconductor layers in the device structure formed thereon may be improved, but also the light extraction efficiency of the light-emitting device 1 is improved, thereby the external quantum efficiency is enhanced.

In some embodiments, when a portion of the base material is removed by a combination of the supply modes of the reactive gas source and the heat treatment, the epitaxial temperature is not less than 1200° C., and the epitaxial growth duration is not less than 40 minutes. In some embodiments, the epitaxial temperature is not less than 1300° C., and the epitaxial growth duration is not less than 50 minutes. In some embodiments, the epitaxial temperature is between about 1200° C. and about 1500° C., and the epitaxial duration is between about 40 minutes and about 70 minutes.

Several methods of supplying a reactive gas source to form the holes 11 of the embodiment are provided below for illustration. Nevertheless, the present disclosure is not limited to the process conditions, numerical values, and/or ranges described below.

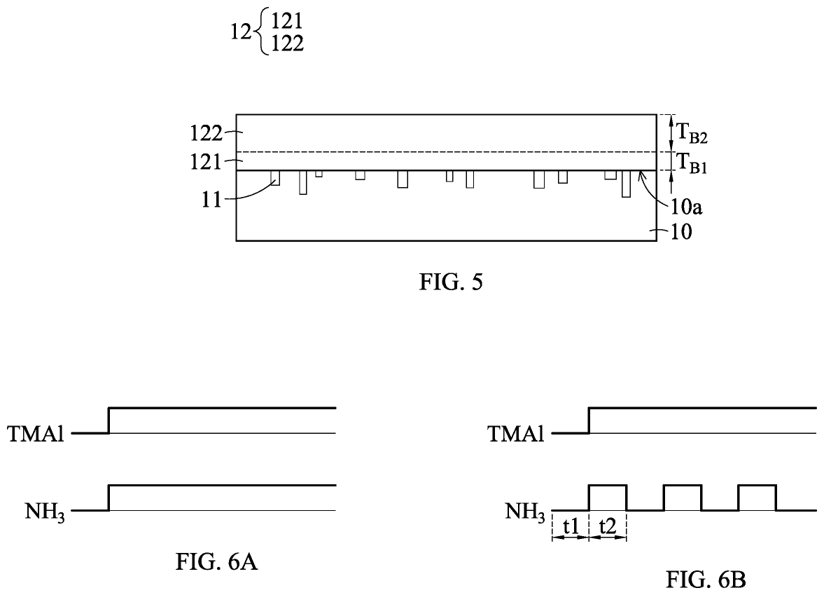

FIG. 5 illustrates a schematic cross-sectional view of growing a buffer layer on a substrate in accordance with some embodiments of the present disclosure. The buffer layer 12 formed on the substrate 10 includes a first buffer portion 121 and a second buffer portion 122. In accordance with some embodiments, by providing different supply modes of gas sources required by a buffer material to respectively depose the first buffer portion 121 and the second buffer portion 122, the buffer layer 12 may be formed on the upper surface 10a of the substrate 10, thereby making the substrate 10 include the holes 11.

Furthermore, as shown in FIG. 5, the interface between the first buffer portion 121 and the second buffer portion 122 is a continuous surface. That is, after epitaxially growing the first buffer portion 121, a top surface of the first buffer portion 121 may be flatter due to the coalesced buffer material. In some embodiments, the first buffer portion 121 has a first thickness TB1, and the second buffer portion 122 has a second thickness TB2. The second thickness TB2 is greater than the first thickness TBT. The second buffer portion 122 is two-dimensionally grown with a certain thickness to reduce the defect density, thereby improving the epitaxy quality. In some embodiments, the first thickness TB1 of the first buffer portion 121 is approximately 1 μm.

In an embodiment, when the buffer layer 12 includes aluminum nitride (AlN), a nitrogen-containing gas and an aluminum-containing gas are used to form the buffer layer 12 of aluminum nitride, and aluminum nitride may be epitaxially grown on the substrate 10 by different gas supply modes, and the upper surface 10a of the substrate 10 is randomly etched at the same time to form the holes 11. In some embodiments, a nitrogen-containing gas and an aluminum-containing gas are provided in a first mode to epitaxially grow the first buffer portion 121 on the upper surface 10a of the substrate 10, and a nitrogen-containing gas and an aluminum-containing gas are provided in a second mode to epitaxially grow the second buffer portion 122 on the first buffer portion 121. The nitrogen-containing gas can be ammonia gas (NH3), and the aluminum-containing gas can be trimethylaluminum (TMAl). The second mode may be the same as or different from the first mode. In an embodiment, the second mode is different from the first mode.

The following describes the relevant gas supply modes of buffer materials to illustrate several embodiments for epitaxially growing the buffer layer.

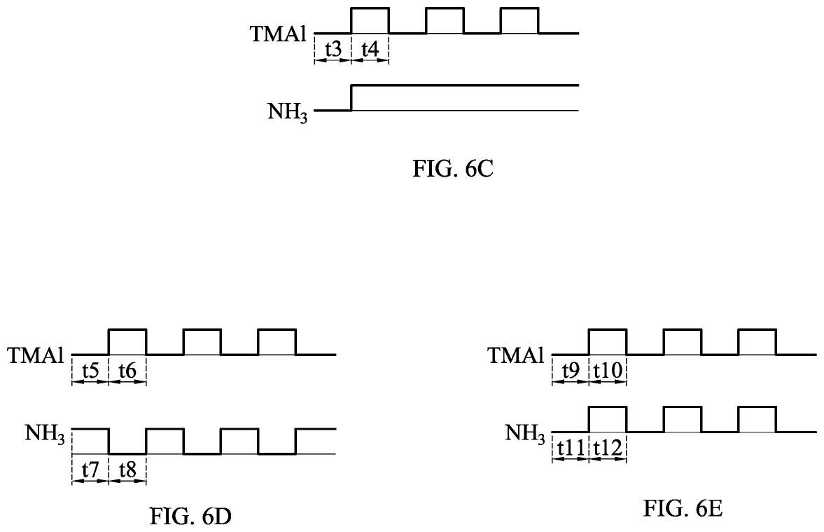

FIGS. 6A, 6B, 6C, 6D and 6E show schematic diagrams of various supply modes of different gas sources when depositing a buffer layer on a substrate in some embodiments of the present disclosure. In some embodiments, the gas source supply modes as shown in FIGS. 6A to 6E may be used for the first buffer portion 121 and/or the second buffer portion 122 of the epitaxial growth embodiment. Referring to FIGS. 6A to 6E, in an illustrative embodiment, ammonia gas (NH₃) and trimethylaluminum (TMAl) are respectively used as the nitrogen source and the aluminum source to form an aluminum nitride (AlN) buffer layer.

In some embodiments, referring to FIGS. 5 and 6A, the buffer layer 12 of aluminum nitride is formed on the upper surface 10a of the substrate 10 by continuously supplying ammonia gas (NH₃) (nitrogen-containing gas) and trimethylaluminum (TMAl) (aluminum-containing gas). The above mode may be suitable for forming the first buffer portion 121 and/or the second buffer portion 122. In some embodiments, ammonia gas and TMAl may be provided simultaneously and continuously, as shown in FIG. 6A. In some embodiments, supplies of ammonia gas and TMAl (not shown) may be started at different times, for example, after ammonia gas is continuously supplied for a time period (such as few seconds), and then start to continuously provide TMAl, or first continuously provide TMAl for a time period, and then start to continuously provide ammonia gas.

In some embodiments, referring to FIGS. 5 and 6B, ammonia gas (NH₃) (nitrogen-containing gas) may be provided by a pulse mode and trimethylaluminum (TMAl) (aluminum-containing gas) may be provided in a continuous mode to form the buffer layer 12 of aluminum nitride on the upper surface 10a of the substrate 10. The above modes may be suitable for forming the first buffer portion 121 and/or the second buffer portion 122. In some embodiments, the pulse mode for supplying ammonia gas (nitrogen-containing gas) includes a continuous closing duration t1 and a continuous introducing duration t2 alternating with the continuous closing duration t1. As shown in FIG. 6B, the continuous closing duration t1 is also the pulse width when ammonia gas (nitrogen-containing gas) is closed, and the continuous introducing duration t2 is also the pulse width when ammonia gas (nitrogen-containing gas) is introduced. In an embodiment, the continuous introducing duration t2 of ammonia gas (nitrogen-containing gas) may be equal to or different from (greater or smaller than) the continuous closing duration t1 of ammonia gas. That is, t2=t1, or t2>t1, or t2<t1.

In addition, although in the embodiment of FIG. 6B, in order to form the buffer layer 12, ammonia gas and TMAl are introduced at the same time to supply nitrogen by a pulse mode and continuously supply aluminum, the disclosure is not limited thereto. In some other embodiments, ammonia gas may also be provided by a pulse mode for a time period (such as a continuous introducing duration t2 or other duration), and then a continuous supply of TMAl (not shown) may be started. Alternatively, TMAl may be supplied continuously for a time period, and then ammonia gas may be supplied by a pulse mode (not shown).

In some embodiments, referring to FIGS. 5 and 6C, the buffer layer 12 of aluminum nitride is formed on the upper surface 10a of the substrate 10 by supplying trimethylaluminum (TMAl) (aluminum-containing gas) by a pulse mode and ammonia gas (NH₃) (nitrogen-containing gas) continuously. The above modes may be suitable for forming the first buffer portion 121 and/or the second buffer portion 122. In some embodiments, the pulse mode for supplying TMAl (aluminum-containing gas) includes a continuous closing duration t3 and a continuous introducing duration t4 alternating with the continuous closing duration t3. As shown in FIG. 6C, the continuous closing duration t3 is also the pulse width when TMAl (aluminum-containing gas) is closed, and the continuous on duration t4 is also the pulse width when TMAl (aluminum-containing gas) is introduced. In accordance with some embodiments, the continuous introducing duration t4 of TMAl may be equal to or different from (greater or smaller than) the continuous closing t3 of TMAL. That is, t4=t3, or t4>t3, or t4<t3.

In addition, although in the embodiment of FIG. 6C, in order to form the buffer layer of aluminum nitride, ammonia gas and TMAl are provided at the same time to continuously supply the nitrogen source and supply the aluminum source by a pulse mode, the present disclosure is not limited thereto. In some other embodiments, TMAl may also be provided by a pulse mode for a time period (such as a continuous introducing duration t4 or other suitable duration), and then ammonia gas may be continuously provided (not shown), or ammonia gas may be supplied continuously for a time period, and then TMAl may be supplied by a pulse mode (not shown).

In some embodiments, referring to FIGS. 5 and 6D, the buffer layer 12 of aluminum nitride is formed on the upper surface 10a of the substrate 10 by supplying trimethylaluminum (TMAl) (aluminum-containing gas) by a pulse mode and ammonia gas (NH₃) (nitrogen-containing gas) by a pulse mode. The above modes may be suitable for forming the first buffer portion 121 and/or the second buffer portion 122. In some embodiments, the pulse mode for supplying TMAl (aluminum-containing gas) includes a continuous closing duration t5 and a continuous introducing duration t6 alternating with the continuous closing duration t5. The pulse mode for supplying ammonia gas (nitrogen-containing gas) includes a continuous introducing duration t7 and a continuous closing duration t8 alternating with the continuous introducing duration t7. As shown in FIG. 6D, the continuous closing durations t5 and t8 are also the pulse widths when TMAl is closed and ammonia gas is closed respectively, and the continuous introducing durations t6 and t7 are also the pulse widths when TMAl is introduced and ammonia gas is introduced respectively. In accordance with some embodiments, the continuous introducing duration t6 of TMAl is equal to or different from (greater or smaller than) the continuous closing duration t5 of TMAl. That is, t6=t5, or t6>t5, or t6<t5. In accordance with some embodiments, the continuous introducing duration t7 of ammonia gas may be equal to or different from (greater or smaller than) the continuous closing duration t8 of ammonia gas. That is, t7=t8, or t7>t8, or t7<t8.

In addition, although in the embodiment of FIG. 6D, the buffer layer of aluminum nitride is formed by the following steps: firstly introducing ammonia gas and closing TMAl at the same time, and after supplying ammonia gas for a time period (such as continuous introducing duration t7 or other suitable duration), closing ammonia gas and introducing TMAl at the same time, and after supplying TMAl for a time period (such as a continuous introducing duration t6 or other suitable duration), repeating above pulse cycle. But the disclosure is not limited thereto. In some other embodiments, TMAl may also be introduced firstly and ammonia gas may be closed at the same time, and after TMAl is provided for a time period (such as continuous introducing duration t7 or other suitable duration), TMAl may be closed and ammonia gas may be introduced at the same time, and then repeating above pulses cycle that firstly introducing ammonia gas. In addition, in some embodiments, after introducing ammonia gas for a time period by a pulse mode, introducing TMAl by a pulse mode without closing the ammonia gas (not shown).

Furthermore, although in the embodiment of FIG. 6D, the continuous introducing duration t7 of ammonia gas (nitrogen-containing gas) is equal to the continuous closing duration t5 of TMAl (aluminum-containing gas) (t5=t7), and the continuous closing duration t8 of ammonia gas is equal to the continuous introducing duration t6 of TMAl (t6=t8), but the present disclosure is not limited thereto. In accordance with some other embodiments, the continuous introducing duration t7 of ammonia gas may not be equal to (such as greater than or less than) the continuous closing duration t5 of TMAl, and the continuous closing duration t8 of ammonia gas may not be equal to (such as greater than or less than) the continuous introducing duration t6 of TMAl.

In some embodiments, referring to FIGS. 5 and 6E, the buffer layer 12 aluminum nitride is formed on the upper surface 10a of the substrate 10 by supplying trimethylaluminum (TMAl) (aluminum-containing gas) by a pulse mode and ammonia gas (NH₃) (nitrogen-containing gas) by a pulse mode. The above modes may be suitable for forming the first buffer portion 121 and/or the second buffer portion 122. In some embodiments, the pulse mode for supplying TMAl (aluminum-containing gas) includes a continuous closing duration t9 and a continuous introducing duration t10 alternating with the continuous closing duration t9. The pulse mode for supplying ammonia gas (nitrogen-containing gas) includes a continuous closing duration t11 and a continuous introducing duration t12 alternating with the continuous closing duration t11. As shown in FIG. 6E, the continuous closing durations t9 and t11 are also the pulse widths when TMAl is closed and when ammonia gas is closed respectively, and the continuous introducing durations t10 and t12 are also the pulse widths when TMAl is introduced and when ammonia gas is introduced respectively. In accordance with some embodiments, the continuous introducing duration t10 of TMAl may be equal to or different from (greater or smaller than) the continuous closing duration t9 of TMAl. That is, t10=t9, or t10>t9, or t10<t9. In accordance with some embodiments, the continuous introducing duration t12 of ammonia gas may be equal to or different from (greater or smaller than) the continuous closing duration t11 of ammonia gas. That is, t12=t11, or t12>t11, or t12<t11.

In addition, although in the embodiment of FIG. 6E, the continuous closing duration t9 of TMAl is equal to the continuous closing duration t11 of ammonia gas (t9=t11), and the continuous introducing duration t10 of TMAl is equal to the continuous introducing duration t12 of ammonia gas (t10=t12), so that the pulse waveform of ammonia gas may overlap with the pulse waveform of TMAl, but the present disclosure is not limited thereto. In accordance with some embodiments of the present disclosure, the pulse waveforms of the nitrogen-containing gas may overlap with the pulse waveform of TMAl as FIG. 6E shows, or partially overlap, for example, the pulse mode of the ammonia gas is provided in advance, or the pulse mode of TMAl is provided in advance, or may be staggered from each other as FIG. 6D shows.

Various supply modes of the buffer material gas source as shown in FIGS. 6A, 6B, 6C, 6D, and 6E may be carried out with appropriate process temperatures. For example, the buffer material gas may be supplied at low or high temperatures, so that the holes 11 may be formed on the substrate 10. In some embodiments, the low temperature is between 700° C. and 1100° C., or between other low temperature ranges. In some embodiments, the high temperature is between about 1100° C. and about 1500° C., or between other high temperature ranges.

The following exemplary descriptions relate to some embodiments of methods for forming the buffer layer and the holes. Nevertheless, it should be noted that the buffer material deposition methods and related process parameters disclosed in the embodiments are simply for reference and are not intended to limit the scope of the present disclosure.

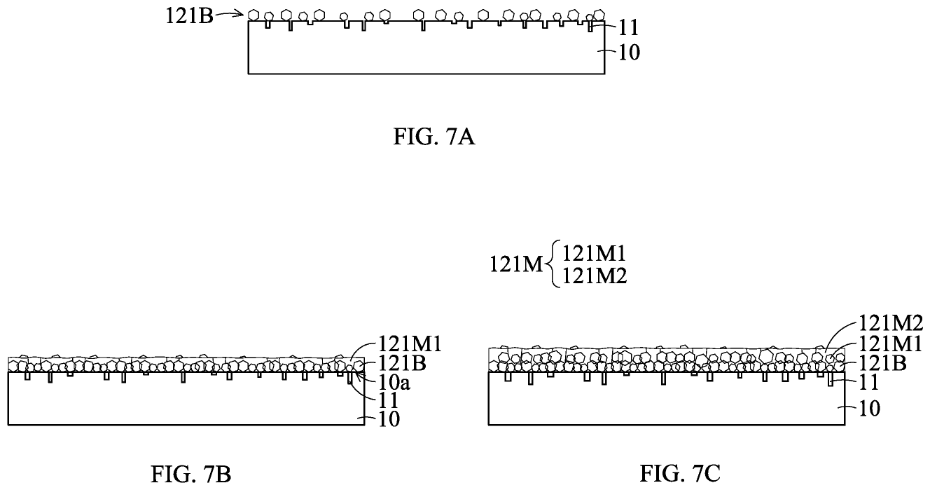

FIGS. 7A to 7E show schematic cross-sectional views of multiple intermediate stages of growing a buffer layer on a substrate in accordance with some embodiments of the present disclosure. In accordance with some embodiments, different buffer material portions may be epitaxially grown on the upper surface 10a of the substrate 10 by changing the supply modes of the gas sources required to deposit the buffer material, thereby making the substrate 10 include the holes 11. FIGS. 7A to 7D illustrate multiple forming stages of the first buffer portion 121 of the buffer layer 12, and FIG. 7E shows the forming stages of the second buffer portion 122 of the buffer layer 12

Referring to FIG. 7A, in some embodiments, a buffer base layer 121B of the first buffer portion 121 is formed on the upper surface 10a of the substrate 10. The buffer base layer 121B may also serve as a nucleation layer for epitaxial growth. In this embodiment, the buffer base layer 121B can be an aluminum nitride (AlN) nucleation layer. In some embodiments, during the epitaxially growth of the buffer base layer 121B, the upper surface 10a of the substrate 10 may be randomly etched at the same time to form the holes 11 randomly distributed and extended downward from the upper surface 10a.

The buffer base layer 121B and the holes 11 may be formed by following supply modes of gas source. Ammonia gas (NH3) (nitrogen-containing gas) and trimethylaluminum (TMAl) (aluminum-containing gas) may be continuously supplied as shown in FIG. 6A. Alternatively, TMAl may be continuously supplied when ammonia gas is supplied by a pulse mode as shown in FIG. 6B. Alternatively, TMAl may be continuously supplied when ammonia gas is continuously supplied as shown in FIG. 6C. Alternatively, ammonia gas and TMAl are supplied by pulse modes but not at the same time as shown in FIG. 6D; . Alternatively, ammonia gas and TMAl are supplied at the same time by pulse modes as shown in FIG. 6E. Furthermore, the buffer base layer 121B and the holes 11 may be formed at a low temperature or a high temperature, and the present disclosure is not limited thereto.

During the epitaxially growth of the buffer layer, different gas sources perform different moving rate on the substrate 10 after entering the reaction chamber. Group III elements, such as aluminum and indium, perform a slower moving rate. If the buffer layer is grown in a general epitaxial mode, before being evenly dispersed on the substrate, the Group III elements may have been quickly reacted with the introduced Group V reaction source, such as nitride element reaction source (ammonia gas) to form a Group III-V compound, so aluminum may be not easily distributed to distant regions. In order to improve the epitaxy quality of the buffer layer, in some embodiments, for example, the gas source supply modes shown in FIGS. 6A to 6E may be used to provide nitrogen-containing gas (ammonia gas) and aluminum-containing gas (TMAl) at a first temperature to form the buffer base layer 121B on the upper surface 10a of the substrate 10. Specifically, under a condition that aluminum-containing gas (TMAl) is supplied by a pulse mode and/or nitrogen-containing gas (ammonia gas) is supplied by a pulse mode, and ammonia gas and TMAl are partially or completely non-simultaneously introduced, the reaction between aluminum element and the nitride element reaction source (ammonia gas) may be postponed, which gives aluminum element more opportunities to move onto the upper surface 10a of the substrate 10 to be laterally spread on the upper surface 10a. After aluminum element is laterally spread on the substrate surface, the next pulse of ammonia gas may react with aluminum on the substrate 10 to form aluminum nitride material that constitutes the buffer layer. The continuous introducing duration of ammonia gas may be equal to, greater than or less than the continuous closing duration of ammonia gas. The continuous introducing duration of TMAl may be equal to, greater than or less than the continuous closing duration of TMAl. In accordance with the embodiment, supplying TMAl and ammonia gas by a pulse mode may give aluminum that has not reacted with the ammonia gas an opportunity to move onto the upper surface 10a of the substrate 10 and laterally spread on more area of the upper surface 10a more easily, thereby allowing the buffer base layer 121B to be grown more uniformly on the upper surface 10a of the substrate 10.

Furthermore, the first temperature may be a low temperature, such as no more than 1100° C. In accordance with some embodiments, the first pulse mode may supply ammonia gas and TMAl at the same time or at different times. In accordance with some embodiments, the continuous introducing duration of ammonia gas in the first pulse mode is different from the continuous closing duration of ammonia gas, and the continuous introducing duration of TMAl is different from the continuous closing duration of TMAl. In an embodiment, the introducing duration of ammonia gas in the first pulse mode is longer than the closing duration of ammonia gas. Nevertheless, the present disclosure is not limited to the content of the embodiment.

Next, referring to FIG. 7B, in some embodiments, a first buffer middle layer 121M1 of the first buffer portion 121 may be formed on the buffer base layer 121B. At this stage, in addition to continuing to epitaxially grow the buffer material on the buffer base layer 121B with an island-shaped structure, the buffer material grows laterally further and therefore results in lateral connection. However, the top surface of the first buffer middle layer 121M1 still has a structure including many grain protrusions. In some embodiments, during the epitaxial growth of the first buffer middle layer 121M1, the upper surface 10a of the substrate 10 may be randomly etched to form more holes 11, and/or there may be an opportunity to simultaneously increase depths and/or widths of the originally formed holes as FIG. 7A shows.

The first buffer middle layer 121M1 shown in FIG. 7B may be formed by following supply modes of gas source. Ammonia gas (NH₃, nitrogen-containing gas) and trimethylaluminum (TMAl, aluminum-containing gas) may be supplied continuously as shown in FIG. 6A. Alternatively, TMAl may be supplied continuously when ammonia gas is supplied by a pulse mode as shown in FIG. 6B. Alternatively, TMAl may be supplied by a pulse mode when ammonia gas is supplied continuously as shown in FIG. 6C. Alternatively, ammonia gas and TMAl are provided in pulse modes but not at the same time as shown in FIG. 6D. Alternatively, ammonia gas and TMAl may be provided in pulse modes simultaneously as shown in FIG. 6E. Furthermore, the first buffer middle layer 121M1 may be formed at a low temperature or a high temperature, and the present disclosure is not limited thereto.

In some embodiments, a nitrogen-containing gas (ammonia gas) and an aluminum-containing gas (TMAl) may be provided in a second pulse mode at a second temperature to form the first buffer middle layer 121M1 on the buffer base layer 121B. That is, TMAl and ammonia gas are provided by a pulse mode. In the second pulse mode, the continuous introducing duration of ammonia gas may be equal to, greater than or less than the continuous closing duration of ammonia gas, and the continuous introducing duration of TMAl may be equal to, greater than or less than the continuous closing duration of TMAl.

Furthermore, in some embodiments, the continuous introducing duration of ammonia gas of the second pulse mode is different from the continuous introducing duration of ammonia gas of the first pulse mode. The continuous closing duration of ammonia gas of the second pulse mode is different from the continuous closing duration of ammonia gas of the first pulse mode. In some embodiments, the continuous introducing duration of TMAl of the second pulse mode is different from the continuous introducing duration of TMAl of the first pulse mode. The continuous closing duration of TMAl of the second pulse mode is different from the continuous closing duration of TMAl of the first pulse mode.

Furthermore, in some embodiments, the second temperature is greater than the first temperature for epitaxially growing the buffer base layer 121B. In some embodiments, the second temperature may be a high temperature, such as no more than 1300° C. In accordance with some embodiments, the second pulse mode may provide ammonia gas and TMAl at the same time or at different time. In accordance with some embodiments, the continuous introducing duration of ammonia gas in the second pulse mode is different from the continuous closing duration of ammonia gas. The continuous introducing duration of TMAl is different from the continuous closing duration of TMAl. In an embodiment, the introducing duration of TMAl in the second pulse mode is longer than the closing duration of TMAl. A longer introducing duration of TMAl may increase aluminum content. However, the present disclosure is not limited thereto.

Referring to FIG. 7C, in some embodiments, the process conditions may be changed, and a second buffer middle layer 121M2 of the first buffer portion 121 is formed on the first buffer middle layer 121M1. At this stage, not only continuing to epitaxially grow the buffer material on the first buffer middle layer 121M1, but also continuing to laterally grow the buffer material, therefore resulting in a higher level of lateral connection and a relatively flat top surface of the second buffer middle layer 121M2. Although the top surface of the second buffer middle layer 121M2 has a lower surface roughness than that of the top surface of the first buffer middle layer 121M1, the top surface of the second buffer middle layer 121M2 still has grain protrusions, and a relatively flat surface after coalescing may be not achieved. In some embodiments, during the epitaxial growth of the second buffer middle layer 121M2, the upper surface 10a of the substrate 10 may be randomly etched to form more holes 11, and/or depths and/or widths of the holes 11 originally formed (FIG. 7B) may be simultaneously increased. In some embodiments, since the second buffer middle layer 121M2 is further away from the upper surface 10a of the substrate 10 than the first buffer middle layer 121M1, even there is a probability of etching the upper surface 10a of the substrate 10 during the process of the second buffer middle layer 121M2, the probability is less than that during the process of the first buffer middle layer 121M1.

The second buffer middle layer 121M2 as shown in FIG. 7C may be formed by following supply modes of gas source. Ammonia gas (NH₃, nitrogen-containing gas) and trimethylaluminum (TMAl, aluminum-containing gas) may be supplied continuously as shown in FIG. 6A. Alternatively, TMAl may be supplied continuously when ammonia gas is supplied by a pulse mode as shown in FIG. 6B. Alternatively, TMAl may be supplied by a pulse mode when ammonia gas is supplied continuously as shown in FIG. 6C. Alternatively, ammonia gas and TMAl are provided in pulse modes but not at the same time as shown in FIG. 6D. Alternatively, ammonia gas and TMAl are provided in pulse modes simultaneously as shown in FIG. 6E. Furthermore, the second buffer middle layer 121M2 may be formed at a low temperature or a high temperature, and the present disclosure is not limited thereto.

In some embodiments, the second buffer middle layer 121M2 is formed on the first buffer middle layer 121M1 by supplying nitrogen-containing gas (ammonia gas) and aluminum-containing gas (TMAl) at a third temperature by pulse modes. The pulse modes may be the same as or different from the second pulse mode. In accordance with some embodiments, the pulse modes may supply ammonia gas and TMAl at the same time or at different times. In an embodiment, a longer introducing duration of TMAl and a shorter closing duration of TMAl may be used for the pulse mode of TMAl, and a longer closing duration of ammonia gas and a shorter introducing duration of ammonia gas may be used for the pulse mode of ammonia gas, thereby forming the second buffer middle layer 121M2.

Furthermore, in some embodiments, the third temperature is greater than the second temperature for epitaxially growing the first buffer middle layer 121M1, and the second buffer middle layer 121M2 is epitaxially formed at the third temperature. In some embodiments, the third temperature may be a high temperature, such as no more than 1500° C., thereby forming the second buffer middle layer 121M2. However, the present disclosure is not limited to the numerical values of the embodiment.

In some embodiments, the process of the buffer base layer 121B is performed at a relatively low process temperature, which allows the buffer material to form appropriate crystal nuclei on the heterogeneous substrate 10 with different lattice constants, thereby prompting subsequent buffer material continue to be grown upward and laterally connected along the crystal nuclei. In the process of forming the second buffer middle layer 121M2 on the buffer base layer 121B, some lattice defects of the buffer base layer 121B and a buffer middle layer stack 121M (including the first buffer middle layer 121M1 and the second buffer middle layer 121M2) may be eliminated by gradually increasing the process temperature, thereby resulting in better epitaxy qualities.

Next, referring to FIG. 7D, in some embodiments, a buffer upper layer 121T of the first buffer portion 121 may be formed on the second buffer middle layer 121M2. At this stage, continuing to epitaxially grow the buffer material form a higher level of lateral connection on the second buffer middle layer 121M2, and a relatively flat surface after coalescing may be achieved. In some embodiments, during the epitaxial growth of the buffer upper layer 121T, the upper surface 10a of the substrate 10 may be randomly etched to form more holes 11, and/or depths and/or widths of the holes 11 as shown in FIG. 7C may be simultaneously increased. In some embodiments, since the buffer upper layer 121T covers the buffer middle layer stack 121M (including the first buffer middle layer 121M 1 and second buffer middle layer 121M2), the buffer base layer 121B and the upper surface 10a of the substrate 10, the substrate 10 may be protected, and damage caused by subsequent processes can be avoided, and the configurations such as density, size, or morphology of the holes 11 can be controlled. In accordance with the embodiment, after the buffer upper layer 121T is formed, the fabrication of the first buffer portion 121 of the buffer layer 12 is completed as well, therefore after the buffer material is coalesced, the top surface 121a of the first buffer portion 121 maybe relatively flat.

The buffer upper layer 121T as shown in FIG. 7D may be formed by following supply modes of gas source. Ammonia gas (NH₃, nitrogen-containing gas) and trimethylaluminum (TMAl, aluminum-containing gas) may be supplied continuously as shown in FIG. 6A. Alternatively, TMAl may be supplied continuously when ammonia gas is supplied by a pulse mode as shown in FIG. 6B. Alternatively, TMAl may be supplied by a pulse mode when ammonia gas is supplied continuously as shown in FIG. 6C. Alternatively, ammonia gas and TMAl are provided in pulse modes but not at the same time as shown in FIG. 6D. Alternatively, ammonia gas and TMAl are provided in pulse modes simultaneously as shown in FIG. 6E. Furthermore, the buffer upper layer 121T may be formed at a low temperature or a high temperature, and the present disclosure is not limited thereto.

In some embodiments, the buffer upper layer 121T is formed by supplying nitrogen-containing gas (ammonia gas) and aluminum-containing gas (TMAl) at a fourth temperature by a third pulse mode. That is, TMAl and ammonia gas are provided by pulse modes. In accordance with some embodiments, the pulse modes may provide ammonia gas and TMAl at the same time or at different times. In the third pulse mode, the continuous introducing duration of ammonia gas may be equal to, greater than or less than the continuous closing duration of ammonia gas, and the continuous introducing duration of TMAl may be equal to, greater than or less than the continuous closing duration of TMAl.

Furthermore, in some embodiments, the continuous introducing duration of ammonia gas of the third pulse mode is different from the continuous introducing duration of ammonia gas of the first pulse mode and/or second pulse mode. The continuous closing duration of ammonia gas of the third pulse mode is different from the continuous closing duration of ammonia gas of the first pulse mode and/or second pulse mode. In some embodiments, the continuous introducing duration of TMAl of the third pulse mode is different from the continuous introducing duration of TMAl of the first pulse mode and/or second pulse mode. The continuous closing duration of TMAl of the third pulse mode is different from the continuous closing duration of TMAl of the first pulse mode and/or second pulse mode.

Furthermore, in some embodiments, the fourth temperature is not greater than the third temperature for epitaxially growing the second buffer middle layer 121M2. In some embodiments, the fourth temperature may be a high temperature, such as no more than 1500° C. In accordance with some embodiments, the continuous introducing duration of ammonia gas in the third pulse mode is different from the continuous closing duration of ammonia gas, and the continuous introducing duration of TMAl is different from the continuous closing duration of TMAl. In an embodiment, the introducing duration of ammonia gas in the third pulse mode is longer than the closing duration of the ammonia gas. However, the present disclosure is not limited to the content of this embodiment.

Next, referring to FIG. 7E, in some embodiments, the second buffer portion 122 is formed on the buffer upper layer 121T having a flat top surface of the first buffer portion 121. In some embodiments, during the epitaxial growth of the second buffer portion 122, the upper surface 10a of the substrate 10 may be randomly etched to form more holes 11, and/or depths and/or widths of the holes 11 as shown in FIG. 7D may be simultaneously increased. In some embodiments, since the second buffer portion 122 covers the lower buffer upper layer 121T, the first and second buffer middle layers 121M1 and 121M2, the buffer base layer 121B and the upper surface 10a of the substrate 10, the substrate 10 may be protected, and damage caused by subsequent processes can be avoided, and the configurations such as density, size, or morphology of the holes 11 can be controlled.

The second buffer portion 122 as shown in FIG. 7E may be formed by following supply modes of gas source. Ammonia gas (NH₃, nitrogen-containing gas) and trimethylaluminum (TMAl, aluminum-containing gas) may be supplied continuously as shown in FIG. 6A. Alternatively, TMAl may be supplied continuously when ammonia gas is supplied by a pulse mode as shown in FIG. 6B. Alternatively, TMAl may be supplied by a pulse mode when ammonia gas is supplied continuously as shown in FIG. 6C. Alternatively, ammonia gas and TMAl are provided in pulse modes but not at the same time as shown in FIG. 6D. Alternatively, ammonia gas and TMAl are provided in pulse modes simultaneously as shown in FIG. 6E. Furthermore, the second buffer portion 122 may be formed at a low temperature or a high temperature, and the present disclosure is not limited thereto.

In some embodiments, the mode of supplying the nitrogen-containing gas (ammonia gas) and the aluminum-containing gas (TMAl) for forming the second buffer portion 122 may be different from that for forming the first buffer portion 121. For example, as shown in FIG. 6A, TMAl is continuously provided and ammonia gas is continuously provided to form the second buffer portion 122. Furthermore, in some embodiments, the second buffer portion 122 may be formed by supplying above gas sources at a high temperature which can be no more than 1500° C.

During the epitaxial growth of the buffer layer 12, the buffer layer 12 formed on the substrate 10 is coalesced above the holes because of the laterally epitaxial growth in regions devoid of the holes. Therefore, the extension directions of the defects may be changed, and the defects may be restrained in some regions, so the defect density of the following-grown epitaxial layer can be reduced, thereby the epitaxy quality of the buffer layer 12 can be improved, and a full width at half maximum (FWHM) of the buffer layer 12 in an X-ray diffraction (XRD) analysis may be narrower. In some embodiments, as the buffer layer 12 shown in FIGS. 5 and 7E, for example, an X-ray irradiates the buffer layer 12 with a thickness of about 3 μm. An X-ray diffraction pattern of the <002> crystal phase includes a FWHM between 100 arcsec and 300 arcsec. In some embodiments, the FWHM is between 150 arcsec and 200 arcsec. In some embodiments, the FWHM is between 250 arcsec and 500 arcsec. In some embodiments, the FWHM is between 300 arcsec and 400 arcsec.

In addition, since the aluminum-containing gas and the nitrogen-containing gas are supplied in pulse modes and alternately introduced and closed, aluminum that has not reacted with ammonia gas may have an opportunity to move over the surface of the substrate. In this way, aluminum is spread laterally to more areas of the surface of the substrate more easily, thereby the buffer layer may be grown more uniformly on the substrate surface, so the buffer layer can have a smaller surface roughness (root mean square roughness (Rq)). In some embodiments, the buffer layer 12 shown in FIGS. 5 and 7E is measured and analyzed using an atomic force microscope (atomic force microscope; AFM). The scanning area is 20 μm×20 μm, and the root mean square roughness Rq is between 0.5 nm to 5.0 nm. In some embodiments, Rq is between 0.5 nm to 3.0 nm.

In accordance with some embodiments, by forming the first buffer portion 121 of the buffer layer 12 by the above modes (for example, in a pulse mode), the defect density of the first buffer portion 121 may be reduced, and the buffer layer 12 may be flatter after being laterally grown and coalesced. The epitaxy qualities of the buffer layer 12 and other semiconductor layers formed on the buffer layer 12 may be improved, thereby improving the epitaxy qualities of the semiconductor device. In according with some embodiments, the pulse modes may enable the buffer layer 12 to grow more uniformly on the surface of the substrate and increase more areas of the upper surface 10a of the substrate 10 to be exposed in a high-temperature growth environment. Therefore, a probability to form the holes by randomly etching the upper surface 10a of substrate 10 During the formation of the buffer material may be increased. In a duration of growing the buffer layer 12, the buffer layer 12 on the substrate 10 is coalesced above the holes by laterally epitaxial growth in the regions devoid of the holes, thereby the extension directions of the defects may be changed, and the defects may be restrained in some regions, so the defect density of the following-grown epitaxial layer can be improved, thereby the epitaxy qualities of the buffer layer 12 and other semiconductor layers thereon are improved. In accordance with the difference of refractive index between the substrate 10 and the holes 11, a light emitted into the substrate 10 may be refracted, thereby suppressing total internal reflection (TIR).

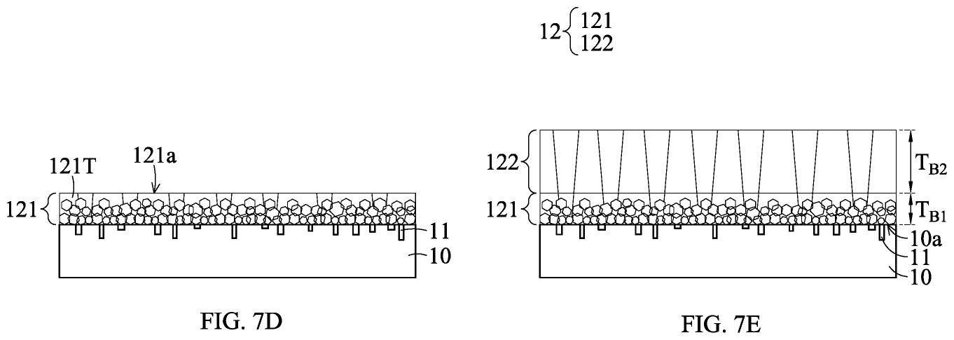

FIG. 8 is a schematic cross-sectional view of a light emitting package in accordance with some embodiments of the present disclosure. As shown in FIG. 8, a light-transmitting body 102P covers the upper surface of the reflective cavity 104P, the circuit board 106P is disposed on the lower surface of the reflective cavity 104P, and the light-emitting device 100P is electrically connected to the circuit board 106P by metal bumps 108a and 108b. The light-emitting device 100P may be the light-emitting device 1 in the foregoing embodiments.

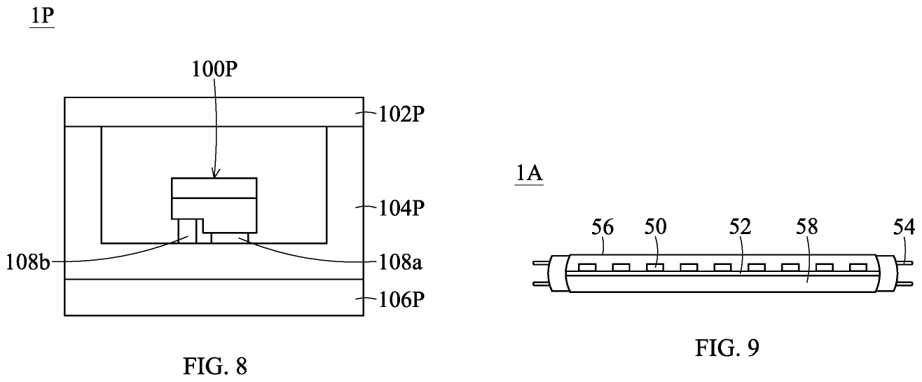

FIG. 9 schematically shows a light emitting device 1A in accordance with some embodiments of the present disclosure. The light-emitting device 1A includes a light-emitting unit 50 mounted on a circuit board 52 in a shape of long-flat plate. A plurality of light-emitting units 50 are disposed on one side of the circuit board 52, and arranged at intervals from each other along the longitudinal direction of the circuit board 52. On the other side of the circuit board 52, a heatsink 58 is provided to dissipate the heat generated by the light-emitting unit 50. On the side where the light-emitting unit 50 is mounted, a transparent cover 56 made of a material that may be easily passed through by emitted-light of the light-emitting unit 50 is provided. In addition, for providing electric power to the circuit board 52, terminals 54 are provided at both ends of the light-emitting device 1A to connect to a power source (not shown). The light-emitting unit 50 may be the light-emitting device 1 or light-emitting device 100P of the foregoing embodiments.

In summary, the substrate including holes provided in some embodiments of the present disclosure can reduce the defect density of the buffer layer, thereby improving the epitaxy qualities of the buffer layer and other semiconductor layers on the buffer layer in the device structure. In addition, the substrate including the holes may be located on the light-emitting side of the light-emitting device, which may improve the light extraction efficiency of the light-emitting device, thereby increasing the external quantum efficiency. Furthermore, in accordance with the methods proposed in the embodiments, the holes provided in the embodiments may be formed on the upper surface of the substrate by epitaxial growths, so it is unnecessary to perform an additional patterning process on the substrate, thereby simplifying the process. Furthermore, in accordance with the methods proposed in the embodiments, the buffer layer may be grown more uniformly on the surface of the substrate, thereby allowing the buffer layer to have a smaller roughness.

What is claimed is:

1. A semiconductor device, comprising:
a substrate, comprising an upper surface;
a buffer layer, formed on the upper surface; and
an element structure, formed on the buffer layer;
wherein the substrate comprises a plurality of holes extending from the upper surface of the substrate to an inside of the substrate and forming a plurality of openings at the upper surface of the substrate; and
wherein in a cross-sectional view of the semiconductor device, at least two of the holes have different depths.

2. The semiconductor device of claim 1, wherein the plurality of openings is irregularly distributed on the upper surface of the substrate.

3. The semiconductor device of claim 1, wherein a distribution density of the plurality of openings on the upper surface of the substrate is in a range of 1E7 cm⁻² to 1E10 cm⁻².

4. The semiconductor device of claim 1, wherein at least two of the openings have different maximum widths on the upper surface of the substrate.

5. The semiconductor device of claim 1, wherein the element structure comprises a semiconductor light-emitting stack formed on the buffer layer, wherein the semiconductor light-emitting stack comprises a first-type semiconductor layer, a second-type semiconductor layer and an active region formed between the first-type semiconductor layer and the second-type semiconductor layer.

6. The semiconductor device of claim 5, wherein the plurality of openings each comprises a maximum width on the upper surface of the substrate, and the maximum width is less than or equal to a maximum wavelength of the light emitted by the active region.

7. The semiconductor device of claim 5, wherein in the cross-sectional view the plurality of holes each comprises a depth that is less than a maximum wavelength of the light emitted by the active region.

8. The semiconductor device of claim 7, wherein the depth does not exceed twice a minimum wavelength of light emitted by the active region.

9. The semiconductor device of claim 1, wherein each of the plurality of openings on the upper surface of the substrate comprises a maximum width between 1 nm and 100 nm.

10. The semiconductor device of claim 1, wherein in the cross-sectional view the plurality of holes each comprises a depth between 10 nm and 200 nm.

11. The semiconductor device of claim 1, wherein a depth difference of at least two of the holes and/or a maximum width difference of at least two of the openings is between 5 nm and 100 nm.

12. The semiconductor device of claim 1, wherein the buffer layer comprises a full width at half maximum (FWHM) between 100 arcsec and 300 arcsec in an X-ray diffraction pattern of <002> crystal phase, or between 250 arcsec and 500 arcsec in the X-ray diffraction pattern of <002> crystal phase.

13. The semiconductor device of claim 1, wherein the buffer layer comprises a root mean square roughness between 0.5 nm and 5.0 nm.

14. A method for forming a semiconductor device, comprising steps of:
providing a substrate comprising an upper surface;
epitaxially forming a buffer layer on the upper surface, and after forming the buffer layer, the substrate comprises a plurality of holes, and a plurality of openings is formed by the plurality of holes at the upper surface of the substrate; and
forming an element structure on the buffer layer.

15. The method of claim 14, further comprising a step of heat treatment before, after or when forming the buffer layer, and the temperature of the heat treatment step is not less than 1200° C. and the duration thereof is not less than 40 minutes.

16. The method of claim 14, wherein the step of epitaxially forming the buffer layer comprises:
supplying a nitrogen-containing gas and an aluminum-containing gas by a first mode to epitaxially grow a first buffer portion on the upper surface of the substrate; and
supplying the nitrogen-containing gas and the aluminum-containing gas by a second mode to epitaxially grow a second buffer portion on the first buffer portion;
wherein the first mode comprises supplying the nitrogen-containing gas and/or the aluminum-containing gas by a pulse mode, and the second mode comprises supplying the nitrogen-containing gas and the aluminum-containing gas simultaneously and continuously.

17. The method of claim 16, wherein the step of epitaxially growing the first buffer portion comprises:
supplying the nitrogen-containing gas and the aluminum-containing gas by a first pulse mode to form a buffer base layer on the upper surface of the substrate; and
supplying the nitrogen-containing gas and the aluminum-containing gas by a second pulse mode to form a buffer middle stack on the buffer base layer;
wherein in the first pulse mode and/or the second pulse mode, an introducing duration and a closing duration of the nitrogen-containing gas are different, and an introducing duration and a closing duration of the aluminum-containing gas are different; and
wherein the introducing duration and/or the closing duration of the nitrogen-containing gas in the first pulse mode are different from those in the second pulse mode, and the introducing duration and/or the closing duration of the aluminum-containing gas in the first pulse mode are different from those in the second pulse mode.

18. The method of claim 17, wherein the step for epitaxially growing the first buffer portion further comprises:
supplying the nitrogen-containing gas and the aluminum-containing gas by a third pulse mode to form a buffer upper layer on the buffer middle stack;
wherein the third pulse mode is different the first pulse mode and/or the second pulse mode.

19. The method of claim 18, wherein an introducing duration of the nitrogen-containing gas in the third pulse mode is different from those in the first pulse mode and/or the second pulse mode.

20. The method of claim 16, wherein during epitaxially growing the first buffer portion, the upper surface of the substrate is randomly etched to form the holes extended toward an inside of the substrate.
